(19) United States
(12) Patent Application Publication
(10) Pub. No.: US 2006/0001096 A1
(43) Pub. Date: Jan. 5, 2006

(54) Photodetector using mosfet with quantum channel and manufacturing method thereof

(75) Inventors: Hong Goo Choi, Seongnam-si (KR); Hoon Kim, Seoul (KR)

Correspondence Address: GREENBLUM & BERNSTEIN, P.L.C., 1950 ROLAND CLARKE PLACE, RESTON, VA, 20191, US

(73) Assignee: Korea Electronics Technology Institute, Seongnam-si (KR)

(21) Appl. No.: 10/530,416

(22) PCT Filed: Aug. 18, 2003
(86) PCT No.: PCT/KR03/01658

§ 371 Date: Apr. 7, 2005

(30) Foreign Application Priority Data
Oct. 24, 2002 (KR) 10-2002-0065314

(51) Int. Cl. H01L 27/01

(52) U.S. Cl. 257/353

(57) ABSTRACT

The present invention relates to a photodetector using MOSFET with quantum channels and a method for making thereof. A photodetector using MOSFET with quantum channels according to the present invention comprises a quantum channel formed on an activated SOI wafer, a gate oxide film covering said quantum channel; a gate formed so as to control carrier current at said quantum channel; a source and a drain formed at both ends of said channel area; and metal layers connected with said gate, said source and said drain. Thus, the photodetector according to the present invention can obtain more excellent photocurrent characteristics compared with the existing SOI MOSFET device by forming quantum channels on the SOI MOSFET. The MOSFET with quantum channels according to the present invention can be used as a good photodetector maintaining advantages of the existing MOSFET such as ease in integration and high speed.

### TECHNICAL FIELD

The present invention relates to a photodetector a using metal-oxide-semiconductor field effect transistor (hereinafter referred to as “MOSFET”) with quantum channels and a manufacturing method thereof and, more particularly, to a photodetector having advantages of MOSFET device by forming quantum channels based on the structure of silicon on insulator (hereinafter referred to as “SOI”) MOSFET to obtain excellent photocurrent characteristics compared with an existing SOI MOSFET and a method for making the photodetector.

### BACKGROUND ART

Among various devices used as a photodetector, one of the most sensitive devices is photomultiplier. The basic structure of this device is a vacuum tube containing a light-sensitive photocathode and an electron multiplier. Disadvantages of photomultipliers are relatively high cost and need for high voltage, which limit and complicate their versatility. Also, there are various semiconductor photodetectors such as photodiodes, phototransistors, and charge coupled devices (hereinafter referred to as “CCDs”). Among them, photodiodes have been used broadly and studied actively in order to obtain more efficient photocurrent characteristics. However, a problem with detectors using semiconductor devices is that the carriers have to migrate in the bulk of semiconductor material where thermal energy produces a high background noise.

To solve such problems, an approach to photodetectors using MOSFET has been carried out. For example, U.S. Pat. No. 6,043,508 discloses a MOSFET photodetector having a floating gate. MOSFET devices can be used as good devices for photodetectors because of miniaturization of components and power saving according to cheap price, good sensitivity and ease in integration. However, a MOSFET as a photodetector cannot generally distinguish electron-hole pairs generated by light from electron-hole pairs generated naturally in room temperature. Therefore, such a MOSFET has disadvantages such as low sensitivity and large initial dark current. In addition, such a MOSFET has not been systematically studied up to now.

### DISCLOSURE OF INVENTION

Accordingly, the present invention is directed to a photodetector using a MOSFET with quantum channels and a manufacturing method thereof that substantially obviates one or more problems due to limitations and disadvantages of the related art.

An object of the present invention is to provide a photodetector using a MOSFET where quantum channels are formed on a structure of an existing SOI MOSFET in order to obtain more excellent photocurrent characteristics, and a method for making such a photodetector.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

The present invention provides a photodetector using a MOSFET with quantum channels, which is based on a structure of SOI MOSFET, the SOI MOSFET according to the present invention comprising:
a quantum channel (2) formed on an activated SOI wafer (1);
a gate oxide film (3) covering said quantum channel;
a gate (4) formed so as to control carrier current at said quantum channel;
a source (5) and a drain (6) formed at both ends of said channel area; and
metal layers (7) connected with said gate, said source and said drain.

Thus, the SOI MOSFET according to the present invention has advantages of lower dark current and higher sensitivity compared with an existing simple SOI MOSFET.

It is to be understood that both the foregoing general description and the following detailed description of the present invention are exemplary and explanatory and are intended to provide further explanation of the invention as claimed.

### BRIEF DESCRIPTION OF THE DRAWINGS

Further objects and advantages of the invention can be more fully understood from the following detailed description taken in conjunction with the accompanying drawings, in which:

FIG. 1 is a cross-sectional view of an SOI MOSFET photodetector according to the present invention;

FIG. 2 is a top plane view of an SOI MOSFET photodetector according to the present invention; and

FIGS. 3a and 3b are graphs showing photocurrent response characteristics of a MOSFET.

### BEST MODE FOR CARRYING OUT THE INVENTION

Reference will now be made in detail to the preferred embodiments of the present invention, examples of which are illustrated in the accompanying drawings.

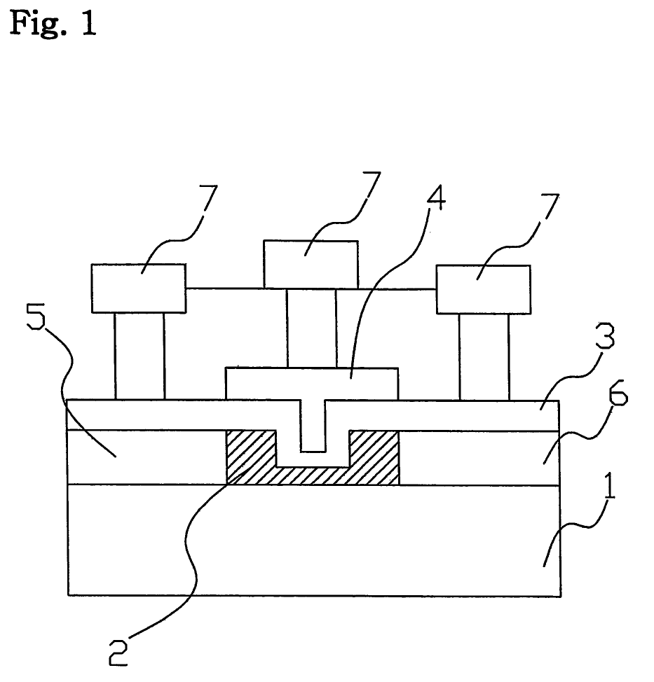

FIG. 1 is a cross-sectional view of an SOI MOSFET photodetector according to the present invention. The SOI MOSFET photodetector according to the present invention comprises:
an activated SOI wafer (1);
a quantum channel (2) formed on the center of said activated SOI wafer;
a gate oxide film (3) covering said quantum channel;
a gate (4) formed so as to control carrier current at said quantum channel;
a source (5) and a drain (6) formed at both ends of said channel area; and
metal layers (7) connected with said gate, said source and said drain.

The gate oxide film covering the quantum channel comprises oxides including SiO₂ and has a depth of 1 nm˜500 nm. In addition, the gate formed so as to control carrier current can be omitted.

The source (5) and drain (6) have a polarity opposite to that of a channel. For example, if the polarity of the source and drain is N+ type, the polarity of channel area becomes P+ type. On the contrary, if the polarity of the source and drain is P+ type, the polarity of channel area becomes N+ type. The former MOSFET is N−P−N type MOSFET, and the latter is P−N−P type MOSFET. A depth of the source and drain is preferably less than 1,000 nm.

The metal layers connected with the gate, source and drain comprise a metal selected from the group of Al, Ti, W, In, Co, Au, Ni and Cr, or a metal compound including a metal selected from said group.

A method for making an SOI MOSFET according to the present invention comprises the steps of:
forming an activated area on an SOI wafer (1);
forming a quantum channel (2) on the center of said activated area;
forming a gate oxide film (3) on the SOI wafer with said quantum channel;
forming a gate (4) on said gate oxide film using lithography,
forming a source (5) and drain (6) at both ends of said quantum channel; and
depositing metal layers (7) after forming contacts on said gate, said source and said drain.

In the step of forming an activated area, an activated area mask is used, and a photolithography process and an etching process are carried out. In the step of forming a quantum channel, lithography technology including an etching method using a photomask is used. In addition, the step of forming a gate on a gate oxide film using lithography can be omitted.

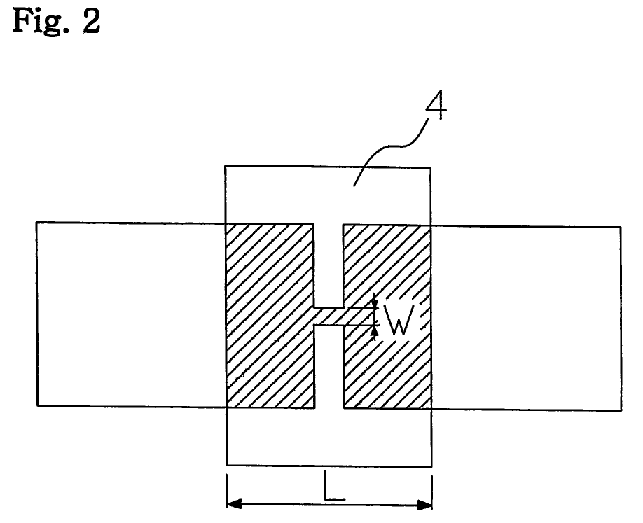

FIG. 2 is a top plane view of an SOI MOSFET photodetector according to the present invention. In FIG. 2, there is only one quantum channel, but the number of quantum channels may be more than one. The length of quantum channel, L, is 1 nm˜1000 nm, and the width of quantum channel, W, is 1 nm˜20 nm.

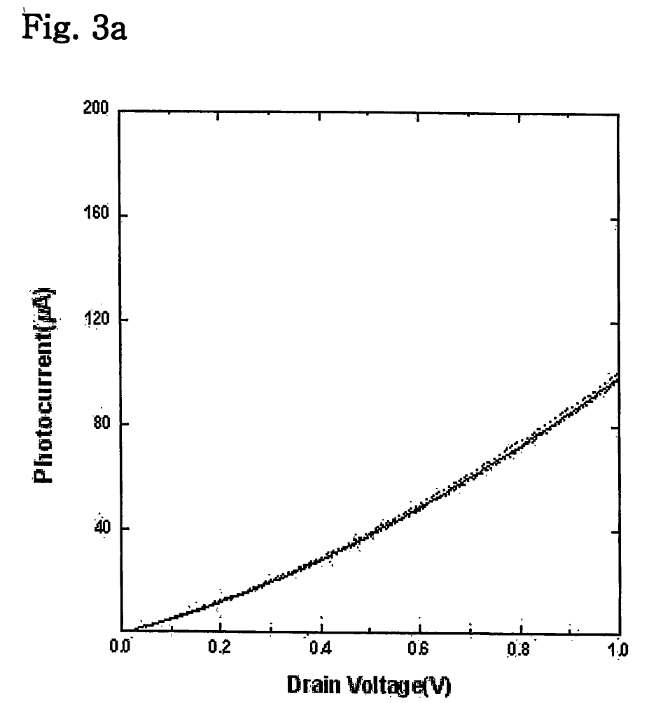

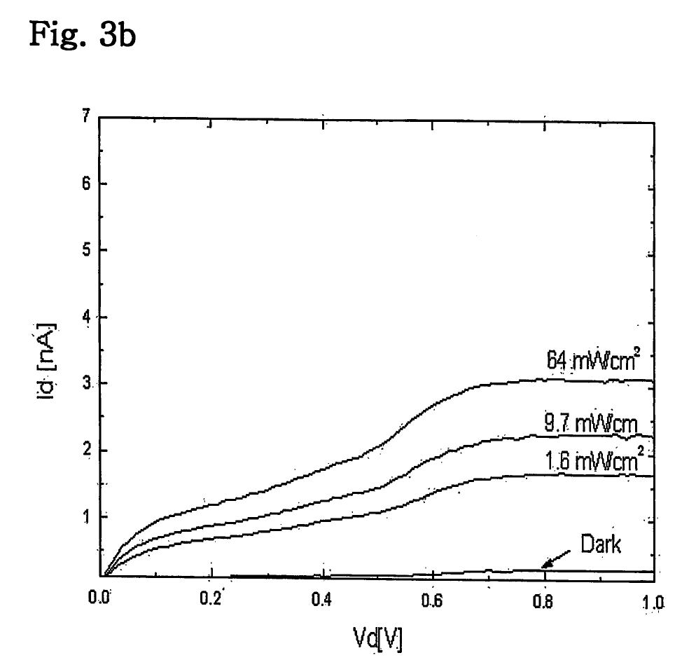

FIGS. 3a and 3b are graphs showing photocurrent response characteristics of a MOSFET. FIG. 3a shows photocurrent response characteristics as a function of drain voltages in an SOI MOSFET which has no quantum channel. FIG. 3b shows photocurrent response characteristics as a function of drain voltages in an SOI MOSFET which has quantum channels.

As shown in FIG. 3a, for the SOI MOSFET without quantum channel, values of initial dark current are hardly distinguished from those of photocurrent by light. Therefore, such SOI MOSFET has very low sensitivity and cannot be used as a photodetector. However, for the SOI MOSFET with quantum channels, as shown in FIG. 3b, the dark current is diminished and photocurrent characteristics due to light can be seen distinctly.

### Industrial Applicability

Thus, the photodetector using a MOSFET with quantum channels according to the present invention can obtain more excellent photocurrent characteristics compared with the existing SOI MOSFET device by forming quantum channels on the SOI MOSFET, although the photodetector of the present invention has a structure of the existing SOI MOSFET as a basic structure. Accordingly, a MOSFET with quantum channels according to the present invention can be used as a good photodetector maintaining advantages of the existing MOSFET such as ease in integration and high speed.

1. A photodetector using MOSFET with quantum channel, comprising:
an SOI wafer activated;
a quantum channel formed on the center of said SOI wafer activated;
a gate oxide film covering said quantum channel;
a source and a drain formed at both ends of said channel area; and
metal layers connected with said source and said drain.

2. The photodetector of claim 1, further comprising a gate formed additionally on said gate oxide film so as to control carrier current in said quantum channel, said gate being connected to the metal layers.

3. The photodetector of claim 1, wherein said gate oxide film comprises oxides including SiO₂.

4. The photodetector of claim 1, wherein said MOSFET comprises N-P-N type MOSFET.

5. The photodetector of claim 1, wherein said MOSFET comprises P-N-P type MOSFET.

6. The photodetector of claim 1, wherein said gate oxide film has a depth of 1 nm˜50 nm.

7. The photodetector of claim 1, wherein said both source and drain have a depth of less than 1000 nm.

8. The phototdetector of claim 1, wherein said metal layers connected with said source and said drain comprise a metal selected from the group consisting of Al, Ti, W, In, Co, Au, Ni, and Cr.

9. The photodetector of claim 1, wherein said metal layers connected with said source and said drain comprise a metal compound including a metal selected form from the group consisting of Al, Ti, W, In, Co, Au, Ni and Cr.

10. A method for making a photodetector using a MOSFET with quantum channel, comprising the steps of:
forming an activated area on SOI wafer;
forming a quantum channel on the center of said activated area;
forming a gate oxide film on the SOI wafer with said quantum channel;
forming a source and a drain at both ends of said quantum channel; and
depositing metal layers after forming contacts on said source and said drain.

11. The method as defined by claim 10, further comprising the steps of:
forming an additional gate on said gate oxide film by means of lithography; and
depositing metal layers after forming contacts on said additional gate.

12. The method as defined by claim 10, wherein the step of forming an activated area is carried out by means of activated area mask, photolithography process, and etching process.

13. The method as defined by claim 10, wherein the step of forming a quantum channel is carried out by means of lithography technology including an etching process using a photomask.

14. The method as defined by claim 10, wherein the number of quantum channels formed is one or more.

15. The method as defined by claim 10, wherein the length of quantum channel formed is 1 nm˜1000 nm.

16. The method as defined by claim 10, wherein the width of quantum channel formed is 1 nm˜20 nm.
